(19) United States
(12) Patent Application Publication
(10) Pub. No.: US 2026/0349056 A1
(43) Pub. Date: Nov. 5, 2026

(54) SENSOR DEVICE

(71) Applicant: Element Six Technologies Limited, Didcot, Oxfordshire (GB)

(72) Inventors: Pierre-Olivier François Marc COLARD, Didcot, Oxfordshire (GB); Andrew Mark EDMONDS, Didcot, Oxfordshire (GB); Matthew Lee MARKHAM, Didcot, Oxfordshire (GB)

(21) Appl. No.: 18/721,392

(22) PCT Filed: Dec. 19, 2022
(86) PCT No.: PCT/EP2022/086752

§ 371 Date: Jun. 18, 2024

(30) Foreign Application Priority Data
Dec. 21, 2021 (GB) 2118622.6

(51) Int. Cl. G01R 33/32; G01R 33/00; G01R 33/032; G01R 33/26

(52) U.S. Cl. CPC G01R 33/323; G01R 33/0005; G01R 33/0023; G01R 33/0094; G01R 33/032; G01R 33/26

(57) ABSTRACT

A sensor device comprising a first sensing surface area and a second sensing surface area. The first sensing surface area and the second sensing surface area are located on a diamond material. The first sensing surface area is within an interactable distance of a first at least one spin defect, and the second sensing surface area is within an interactable distance of a second at least one spin defect, the spin defects being in the diamond material. There is also provided a magnetic excitation source configured to provide a bias magnetic field, a light source configured to excite charge carriers into the conduction band, and a current detector configured to detect charge carriers excited from the one or more spin defect proximate to at least one of the sensing surface areas. The first and second sensing surface areas are optimised for different sensing purposes.

### FIELD

The invention relates to the field of sensor devices, in particular sensor devices formed from diamond material, and also to methods for forming and using such sensor devices.

### BACKGROUND

Point defects in synthetic diamond material, particularly quantum spin defects and/or optically active defects, have been proposed for use in various imaging, sensing, and processing applications including: luminescent tags; magnetometers; spin resonance devices such as nuclear magnetic resonance (NMR) and electron spin resonance (ESR) devices; spin resonance imaging devices for magnetic resonance imaging (MRI); quantum information processing devices such as for quantum communication and computing; magnetic communication devices; and gyroscopes for example.

It has been found that certain defects are particularly useful for sensing and quantum processing applications. For example, the negatively charged nitrogen-vacancy defect (NV⁻) in synthetic diamond material has attracted a lot of interest as a useful quantum spin defect because it has several desirable features including:
(i) Its electron spin states can be coherently manipulated with high fidelity and have an extremely long coherence time (which may be quantified and compared using the transverse relaxation time T₂ and/or T₂*);
(ii) Its electronic structure allows the defect to be optically pumped into its electronic ground state allowing such defects to be placed into a specific electronic spin state even at non-cryogenic temperatures. This can negate the requirement for expensive and bulky cryogenic cooling apparatus for certain applications where miniaturization is desired. Furthermore, the defect can function as a source of photons which all have the same spin state; and
(iii) Its electronic structure comprises emissive and non-emissive electron spin states, which allows the electron, spin state of the defect to be read out through photons. This is convenient for reading out information from synthetic diamond material used in sensing applications such as magnetometry, spin resonance spectroscopy, and imaging. Furthermore, it is a key ingredient towards using NV defects as qubits for long-distance quantum communications and scalable quantum computation. Such results make the NV− defect a competitive candidate for solid-state quantum information processing (QIP).
The NV⁻ defect in diamond consists of a substitutional nitrogen atom adjacent to a carbon vacancy. Its two unpaired electrons form a spin triplet in the electronic ground state (³A), the degenerate ms=±1 sublevels being separated from the ms=0 level by 2.87 GHz. The electronic structure of the NV⁻ defect is such that the ms=0 sublevel exhibits a high fluorescence rate when optically pumped. In contrast, when the defect is excited in the ms=±1 levels, it exhibits a higher probability to cross over to the non radiative singlet state (¹A) followed by a subsequent relaxation into ms=0. As a result, the spin state can be optically read out, the ms=0 state being “bright” and the ms=±1 states being dark. When an external magnetic field or strain field is applied, the degeneracy of the spin sublevels ms=±1 is broken, in the case of a magnetic field this is via the Zeeman interaction. This causes the resonance lines to split depending on the applied magnetic/strain field magnitude and its direction. This dependency can be used for magnetometry by probing the resonant spin transitions using microwaves (MW) and using optically detected magnetic resonance (ODMR) spectroscopy to measure the magnitude and, optionally, the direction of the applied magnetic field.

NV⁻ defects in synthetic diamond material can be formed in a number of different ways including:
(i) formation during growth of the synthetic diamond material where a nitrogen atom and a vacancy are incorporated into the crystal lattice as a nitrogen vacancy pair during growth;
(ii) formation after diamond material synthesis from native nitrogen and vacancy defects incorporated during the growth process by post-growth annealing the material at a temperature (around 800° C.) which causes migration of the vacancy defects through the crystal lattice to pair up with native single substitutional nitrogen defects;
(iii) formation after diamond material synthesis from native nitrogen defects incorporated during the growth process by irradiating the synthetic diamond material to introduce vacancy defects and then subsequently annealing the material at a temperature which causes migration of the vacancy defects through the crystal lattice to pair up with native single substitutional nitrogen defects;
(iv) formation after diamond material synthesis by implanting nitrogen defects into the synthetic diamond material after diamond material synthesis and then annealing the material at a temperature which causes migration of the native vacancy defects through the crystal lattice to pair up with implanted single substitutional nitrogen defects; and
(v) formation after diamond material synthesis by irradiating the synthetic diamond material to introduce vacancy defects, implanting nitrogen defects into the synthetic diamond material before or after irradiation, and annealing the material at a temperature which causes migration of the vacancy defects through the crystal lattice to pair up with implanted single substitutional nitrogen defects.

Various different types of diamond material have been disclosed in the prior art for use in various different types of magnetometry applications including WO2010/010352 and WO2010/010344 which disclose low nitrogen content single crystal chemical vapour deposited (CVD) diamond materials for applications such as magnetometry, and WO2010/149775 which discloses irradiated and annealed single crystal CVD diamond materials for applications such as magnetometry.

Photoelectric Detection of Magnetic Resonance (PDMR) has been proposed as an alternative to ODMR. PDMR allows the direct photoelectric measurement of the spin state of a spin defect in a diamond lattice, based on the detection of charge carriers generated by excited spin centres. This technique is described in Bourgeois, E. et. al., “Photoelectric detection of electron spin resonance of nitrogen-vacancy centres in diamond”. Nature Communications, 6, 2015 and U.S. Pat. No. 10,274,551.

PDMR exploits the change in spin defect photocurrent intensity at magnetic resonance. An advantage of PDMR is that it allows easier integration with electronic systems than ODMR, allows improved detection rates owing to the fast recombination rates and improved resolution owing to the quadratic power dependence of photocurrent.

### SUMMARY

It is an object of the invention to provide a diamond sensor device that addresses problems associated with ODMR, which limits the capabilities to efficiently address independent NV containing regions of diamond sensors or single spin defects within the diamond.

According to a first aspect, there is provided a sensor device comprising a first sensing surface area and a second sensing surface area. The first sensing surface area and the second sensing surface area are located on a diamond material. The first sensing surface area is within an interactable distance of a first at least one spin defect, and the second sensing surface area is within an interactable distance of a second at least one spin defect, the spin defects being in the diamond material. There is also provided a magnetic excitation source configured to provide a bias magnetic field, a light source configured to excite charge carriers into the conduction band, and a current detector configured to detect charge carriers excited from the one or more spin defect proximate to at least one of the sensing surface areas. The first and second sensing surface areas are optimised for different sensing purposes.

As an option, the first sensing surface area and the second sensing surface area are located on a surface of a single diamond material. As an alternative option, the first sensing surface area is located on a surface of a first diamond material and the second sensing surface area is located on a surface of a second diamond material.

Optionally, any of the first and second at least one spin defects are selected from any of a negatively charged nitrogen vacancy centre, a silicon-vacancy centre, a tin vacancy centre, a germanium-vacancy centre, a nickel related defect and a chromium related defect. As a further option, any of the first and second at least one spin defects comprises a single negatively charged nitrogen vacancy centre.

The diamond material optionally comprises any of Chemical Vapour Deposition, CVD, diamond material, natural diamond and high pressure high temperature, HPHT diamond material.

A concentration of spin defects in proximity to the first sensing surface area is optionally different to a concentration of spin defects in proximity to the second sensing surface area.

As an option, any of the first and second sensing surface areas comprises a surface pattern.

As an option, any of the first and second sensing surface areas comprises a metal coating to create an electrical contact.

As an option, the sensing purposes are selected from any of nuclear magnetic resonance, magnetometry, and Radio Frequency spectrum analysis.

Optionally, any of the first and second sensing surface areas in in contact with at least one microfluidic channel.

As an option, any of the first and second sensing areas has a largest linear dimension selected from no more than 5000 μm, no more than 1000 μm, no more than 100 μm, no more than 50 μm, no more than 10 μm and no more than 1 μm.

As an option, the sensor device further comprises a microwave source configured for controlling the spin defect.

According to a second aspect, there is provided a method of forming a sensor device, the method comprising providing a first sensing surface area, and providing a second sensing surface area, wherein the first and second sensing surface areas are located on a diamond material, and wherein the first sensing surface area is within an interactable distance of a first at least one spin defect, and the second sensing surface area is within an interactable distance of a second at least one spin defect. The method further comprises providing a magnetic excitation source configured to provide a bias magnetic field, providing a light source configured to excite charge carriers into the conduction band, and providing a current detector configured to detect charge carriers excited from the one or more spin defect proximate to at least one of the sensing surface areas. The first and second sensing surface areas are optimised for different sensing purposes.

As an option, the method comprises providing both the first sensing surface area and the second sensing surface area on a surface of a single diamond material. As an alternative option, the method comprises providing the first sensing surface area on a surface of a first diamond material, and the second sensing surface area on a surface of a second diamond material.

As an option, any of the first and second at least one spin defects are selected from any of a negatively charged nitrogen vacancy centre, a silicon-vacancy centre, a tin vacancy centre, a germanium-vacancy centre, a nickel related defect and a chromium related defect.

Optionally, a concentration of spin defects in proximity to the first sensing surface area is different to a concentration of spin defects in proximity to the second sensing surface area.

The first and second at least one spin defects are optionally provided by any of doping the diamond during growth, ion implantation, annealing the diamond material, and irradiating the diamond material.

The method optionally further comprises providing a surface pattern on any of the first and second sensing surface areas.

As an option, the method further comprises providing a metal coating of any of the first and second sensing surface areas to create an electrical contact.

According to a third aspect, there is provided a method of using a sensor device as described above in the first aspect, the method comprising locating the sensor device such that the first and second sensing surface areas are in proximity to a substance to be analysed, obtaining a first measurement from the first at least one spin defect, and obtaining a second measurement from the second at least one spin defect.

PDMR allows simpler and smaller interfacing with electronic circuits. Combining this with the sensor device described above allows efficient and precise separate addressing of different regions of the diamond sensor device. This in turn allows the performance of different types of analysis on a single sample with a single sensor.

### BRIEF DESCRIPTION OF DRAWINGS

Non-limiting embodiments will now be described by way of example and with reference to the accompanying drawings in which:

FIG. 1 illustrates schematically a side elevation cross section view of an exemplary sensor device;

FIG. 2 illustrates schematically a side elevation cross section view of a second exemplary sensor device;

FIG. 3 illustrates schematically a side elevation cross section view of a third exemplary sensor device;

FIG. 4 is a flow diagram showing an exemplary method of manufacturing a sensor device;

FIG. 5 illustrates schematically a further exemplary sensor device; and

FIG. 6 is a flow diagram showing an exemplary method of using a sensor device as described herein.

### DETAILED DESCRIPTION

The following description refers to sensors formed from diamond containing at least one spin centre. For convenience, the description refers to the exemplary spin centre being a negatively charged nitrogen-vacancy centre (NV⁻). However, it is known that various spin centres can be formed in diamond. These include silicon-vacancy centres, tin-vacancy centres, germanium-vacancy centres, nickel related defects and chromium-related defects. The skilled person will appreciate that the structure and methods described herein apply to any type of spin centre that can be used in a diamond sensor.

As described above, the complex optical setup associated with ODMR measurements limits the ability to efficiently address independent spin defect-containing regions of a diamond sensor and single NV centres. PDMR allows simpler and smaller interfacing with electronic circuits. It has been found that combining PDMR with patterning methods allows efficient and precise addressing of different sensor regions. This allows multiple types of analysis to be performed on a single sample using a single sensor device.

NV centres in diamond have been shown to be useful for a number of different applications such as magnetic sensing, radio frequency (RF) sensing, Quantum Information Processing (QIP) and so on.

The inventors have developed a device that has more than one sensing region that is interfaced separately with the electronics most appropriate to the sensing mode. These regions can be addressed selectively (separately or simultaneously) to provide measurements on different samples or a sample sitting on or moving through the different regions. Typically, the different regions of the sensor can be provided with different concentrations of spin defects such as NV centres, with the concentrations being adapted for different ranges of sensitivities, different sensing modes (e.g. NMR, magnetometry, hyperpolarization magnetometry, and RF spectrum analysis). As an alternative or addition, difference regions of the sensing device can have different surface patterning or coatings to optimise the type of sensing being performed.

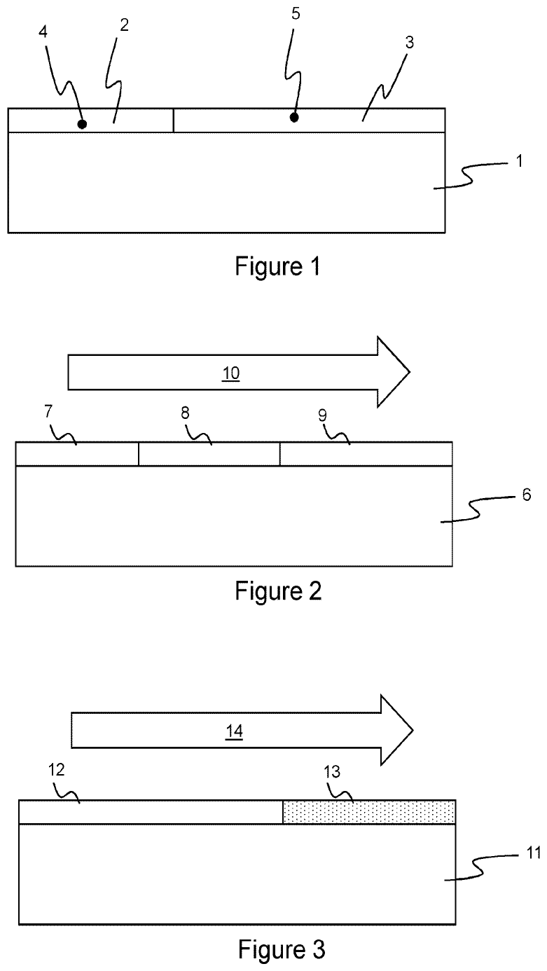

FIG. 1 illustrates a sensor device by way of example. In this example, a diamond sensor device 1 is provided that has a first sensing surface area 2 and a second sensing surface area 3. The first sensing surface area 2 is within an interactable distance of a first at least one spin defect 4, and the second sensing surface area 3 is within an interactable distance of a second at least one spin defect 5. The first sensing surface area 2 is optimised for one type of sensing, and the second surface area 3 is optimized for a different type of sensing.

FIG. 2 illustrates a second exemplary sensor device 6 in which a first sensing area 7 is above a region of diamond having a high concentration of NV centres, and so is optimized for sensitivity. A second sensing area 8 is above a region of diamond having a low concentration of NV centres 8 and so is optimized for high resolution sensing. A third sensing area 9 is above a region of diamond that has an extremely low concentration of NV centres for nano-NMR applications. In use, a fluid 10 flows over it and the same diamond with different sensing areas 7, 8, 9 can be used to simultaneously perform the above-mentioned different types of sensing on the liquid sample by using PDMR to query each sensing area 7, 8, 9 separately. Such a sensor device could be used, for example, in a microfluidic channel for proteomics where the first sensing area 7 is used to detect small magnetic fields, the second sensing area 8 is used to give more precise information on the size and/or number of the detected proteins, and the third sensing area 9 is used to perform nano-NMR on the flowing liquid 10.

FIG. 3 illustrates a third exemplary sensor device 11 in which a first sensing area 12 is above a region of diamond material having a certain concentration of spin defects, and a second sensing area 13 has a surface pattern or coating. For example, a diamond surface may be patterned to enhance nano-NMR capabilities by using a diamond nanograting with a 400 nm pitch and 3 μm depth. Exemplary patterning techniques are described in Bishop et. al., “Deterministic nanopatterning of diamond using electron beams”, ACS Nano 2018, 12, 3, 2873-2882 and Toros et. al., “Reactive ion etching of single crystal diamond by inductively coupled plasma: State of the art and catalog of recipes”, Diamond and Related Materials 108, 107839, 10.1016/j.diamond.2020.107839. Such techniques can be used when targeting PDMR applications even though different specific geometries might be more desirable to optimize the electrode placement.

Where coating such as metallization is used, for example to create necessary electrical contacts, standard photolithography techniques may be used with sub-micron resolutions. An exemplary standard pattern for the electrodes is interdigitated electrodes, as described in Siyushev at. Al., “Photoelectrical imaging and coherent spin-state readout of single nitrogen-vacancy centers in diamond”, Science 15 Feb. 2019, 728-731.

The dimensions of each sensing area depend on the size of the device and the type of sensing that is required. Typically, they may have a largest linear dimension (a diameter in the case of a circular sensing area) of the order of millimetres, but may be no more than 1000 μm, no more than 100 μm, no more than 50 μm, no more than 10 μm and no more than 1 μm. Different methods of surface patterning or metallization all allow minimal dimensions smaller or around the single μm. Considering a sample to measure (for example, a liquid sample in a microfluidic channel), sensing areas might be as small as a few μm for nano-NMR applications and much larger regions (up to mm) for widefield detection of biomarkers.

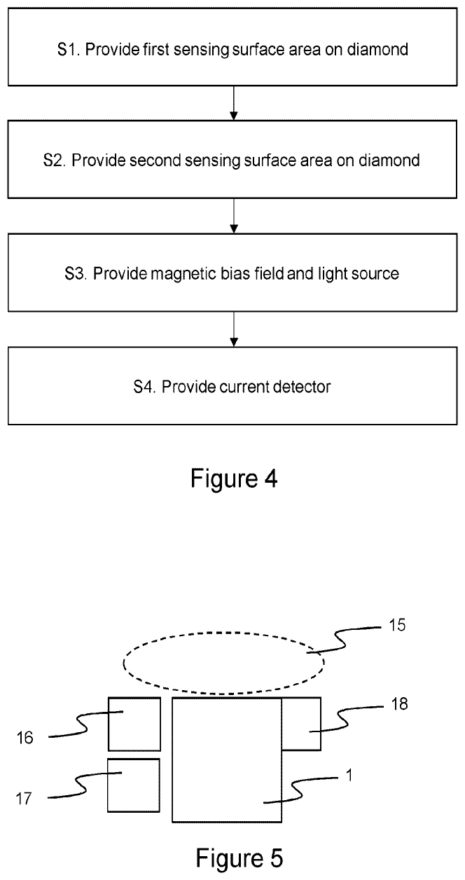

FIG. 4 is a flow diagram illustrating steps for forming a sensor device. The following numbering corresponds to that of FIG. 4:
S1. A first sensing surface area is provided on a diamond material.
S2. A second sensing surface area is provided on a diamond material. The diamond material may be the same diamond material on which the first sensing surface area is provided. Both the first and second sensing surface areas are within an interactable distance of a respective spin defect, so that the spin defects can be used for sensing properties of a substance in contact with or in proximity to each of the first and second sensing surface areas. Exemplary spin defects include a negatively charged nitrogen vacancy centre, a silicon-vacancy centre, a tin-vacancy centre, a germanium-vacancy centre, a nickel related defect and a chromium-related defect. A concentration of spin defects in proximity to the first sensing surface area may be different to a concentration of spin defects in proximity to the second sensing surface area. Furthermore, a surface pattern may be applied to either of the surface of the diamond material at the first or second sensing surface areas, and a metallized coating may be applied to create electrical contacts.
S3. A magnetic excitation source is provided that is configured to apply a bias filed, and a light source is provided to induce the photoelectric effect in the spin defects.
S4. A current detector is provided that is configured to detect charge carriers excited from the one or more spin defect proximate to at least one of the sensing surface areas.

An exemplary method to produce diamond sensors containing different sensing regions in proximity to different concentrations of spin defects can then carried out using the processes one described in WO2020/201211. Nitrogen doping levels are controlled during synthesis to produce layers with different nitrogen concentrations. The substrate is then removed and the remaining material is vertically sliced. After irradiation and annealing, the plate is overgrown with a low-impurity layer such as that described in WO 2001/096634. For example, the diamond sensor device 1 has a lower layer consisting of very low nitrogen impurity diamond. The first sensing surface area 2 is on a layer of diamond material that has nitrogen concentration of 50 ppb, and the second sensing surface area 3 is on a layer of diamond material that has nitrogen concentration of 5 ppm.

A structure like this can be made by growing two layers having different nitrogen concentrations, and subsequently over-growing a low nitrogen layer onto both nitrogen-containing layers. Alternatively, a low nitrogen layer of diamond can be provided and a mask applied before over-growing areas of higher nitrogen concentration. Quite complex structures can be built in this way.

Alternatively, a diamond material with low nitrogen can be provided, such as that described in WO 2001/096634. By masking selected areas, ion implantation can be used to implant spin defects precursor defects that can be treated, for example by irradiation and annealing, to form spin defects such as NV centres. Ion implantation is described in Wannemacher et. al, “Generation and detection of fluorescent color centers in diamond with submicron resolution”. App Phys Lett, 75(20), 3096-3098.

FIG. 5 illustrates a sensor device in which the sensor 1 shown in FIG. 1 is located in proximity to a substance 15 to be sensed. A magnetic bias field 16 is located in proximity to the sensor 1 and generates excitation energy directed to the one or more spin defects in the diamond material. A light source 17 is provided to excite electrons into the conduction band. A current detector 18 is configured to detect charge carriers excited from the one or more spin defect proximate to at least one of the sensing surface areas. One or more photoelectric detectors may be provided. The key point is that the photoelectric detector or detectors can independently query the spin defects in proximity to each of the first and second sensing areas.

In order to independently query each sensing surface area using PDMR, electrodes must be located in proximity to the spin defects associated with each sensing surface area. E-beam lithography techniques allow high-precision deposition of electrodes on a surface. This allows an array of electrodes to be deposited where single NV centres can be selectively addressed by one pair of electrodes. A first benefit of this is that the properties of each NV sensor (orientation, stability) can be quickly assessed, and a map of suitable NV centres can be quickly established. A second benefit is that selected independent single NV centres can be manipulated simultaneously. The distance between single NV centres that can be addressed independently is limited by the resolution of photolithography techniques for the fabrication of electrodes which is better than the diffraction limit. This technology enables improvements for applications using single NV centre arrays and is of particular interest for Quantum Information Processing.

An electrode need not be deposited on the surface of the diamond. PDMR can be optimised if charge collection does not just occur at an electrode disposed at the surface of the diamond, but if an electrically conducting region is provided within the body of the diamond. In this way, charge collection can be optimised to increase the collected signal and sensitivity, and more of the diamond can be utilized. Furthermore, individual spin centres in the diamond can be interrogated. In order to function, the spin centres and the electrically conducting regions must be located within an interactable distance of one another. In practice, this typically means that they are within the drift length of a charge carrier in order for a charge carrier from the spin centre to reach the electrically conducting region and be detected. Under a typical electric field of 5×10⁴ V cm⁻¹, and considering typical mobilities and recombination lifetimes, the theoretical value of the charge carriers' drift length in diamond varies from more than one meter for ultra-high-quality diamond with concentrations of nitrogen impurity in the range of ppb, to less than 20 μm for highly defective diamond.

Note that the device illustrated in FIG. 5 shows a single piece of diamond with two sensing surface areas. It is possible to create a device with a first sensing surface area located on a surface of a first diamond material, and a second sensing surface area located on a second diamond material.

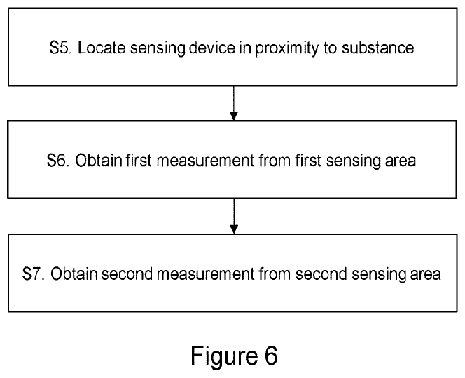

Turning now to FIG. 6, there is shown a flow diagram showing exemplary steps of using the sensor device described above. The following numbering corresponds to that of FIG. 6:
S5. A sensor device having at least a first and second sensing area is located in proximity to a substance to be analysed. The first and second sensing areas are typically optimized to sense different properties, as described above.
S6. A first measurement is obtained from the first at least one spin defect associated with the first sensing area.
S7. A second measurement is obtained from the second at least one spin defect associated with the second sensing area. Note that the first and second measurements may be obtained concurrently or sequentially, depending on the capabilities of the PDMR system and the requirements of sensing.

The invention as defined in the appended claims has been shown and described with reference to the embodiments above. However, it will be understood by those skilled in the art that various changes in form and detail may be made without departing from the scope of the invention as defined by the appended claims, and while exemplary compensation systems have been described, it may be that other types of compensation system to correct for temperature induced B field fluctuations could be used.

1. A sensor device comprising:
a first sensing surface area;
a second sensing surface area
wherein the first sensing surface area and the second sensing surface area are located on a diamond material; and
wherein the first sensing surface area is within an interactable distance of a first at least one spin defect, and the second sensing surface area is within an interactable distance of a second at least one spin defect;
a magnetic excitation source configured to provide a bias magnetic field;
a light source configured to excite spin defects to generate charge carriers into the conduction band; and
a current detector configured to detect charge carriers excited from the one or more spin defect proximate to at least one of the sensing surface areas;
wherein the first and second sensing surface areas are optimised for different sensing purposes; and
wherein a concentration of spin defects in proximity to the first sensing surface area is different to a concentration of spin defects in proximity to the second sensing surface area.

2. The sensor device according to claim 1 wherein the first sensing surface area and the second sensing surface area are located on a surface of a single diamond material.

3. The sensor device according to claim 1 wherein the first sensing surface area is located on a surface of a first diamond material and the second sensing surface area is located on a surface of a second diamond material.

4. The sensor device according to claim 1, wherein any of the first and second at least one spin defects are selected from any of a negatively charged nitrogen vacancy centre, a silicon-vacancy centre, a tin-vacancy centre, a germanium vacancy centre, a nickel related defect and a chromium-related defect.

5.-7. (canceled)

8. The sensor device according to claim 1, wherein any of the first and second sensing surface areas comprises a surface pattern.

9. The sensor device according to claim 1, wherein any of the first and second sensing surface areas comprises a metal coating to create an electrical contact.

10. The sensor device according to claim 1, wherein the sensing purposes are selected from any of nuclear magnetic resonance, magnetometry, and Radio Frequency spectrum analysis.

11.-12. (canceled)

13. The sensor device according to claim 1, further comprising a microwave source configured for controlling the spin defect.

14. A method of forming a sensor device, the method comprising:
providing a first sensing surface area;
providing a second sensing surface area, wherein the first and second sensing surface areas are located on a diamond material, and wherein the first sensing surface area is within an interactable distance of a first at least one spin defect, and the second sensing surface area is within an interactable distance of a second at least one spin defect, and wherein the first and second sensing surface areas are optimised for different sensing purposes and wherein a concentration of spin defects in proximity to the first sensing surface area is different to a concentration of spin defects in proximity to the second sensing surface area;
providing a magnetic excitation source configured to provide a bias magnetic field;
providing a light source configured to excite charge carriers into the conduction band; and
providing a current detector configured to detect charge carriers excited from the one or more spin defect proximate to at least one of the sensing surface areas.

15. The method according to claim 14, comprising providing both the first sensing surface area and the second sensing surface area on a surface of a single diamond material.

16. The method according to claim 14, comprising providing the first sensing surface area on a surface of a first diamond material and the second sensing surface area on a surface of a second diamond material.

17. The method according to claim 14, wherein any of the first and second at least one spin defects are selected from any of a negatively charged nitrogen vacancy centre, a silicon-vacancy centre, a tin-vacancy centre, a germanium vacancy centre, a nickel related defect and a chromium-related defect.

18. (canceled)

19. The method according to claim 14, wherein the first and second at least one spin defects are provided by any of doping the diamond during growth, ion implantation, annealing the diamond material, and irradiating the diamond material.

20. The method according to claim 14, further comprising providing any of a surface pattern and a metal coating on any of the first and second sensing surface areas.

21. (canceled)

22. A method of using a sensor device according to claim 1, the method comprising:
locating the sensor device such that the first and second sensing surface areas are in proximity to a substance to be analysed;
obtaining a first measurement from the first at least one spin defect; and
obtaining a second measurement from the second at least one spin defect.
